(19) United States
(12) Patent Application Publication
(10) Pub. No.: US 2006/0039126 A1
(43) Pub. Date: Feb. 23, 2006

(54) Multilayer structure with device for improving integrity of signals propagating between signal layers

(76) Inventor: Dan Gorcea, Kanata (CA)

Correspondence Address: FETHERSTONHAUGH - SMART & BIGGAR, 1000 DE LA GAUCHETIERE WEST, SUITE 3300, MONTREAL, QC, H3B 4W5, CA

(21) Appl. No.: 10/917,347

(22) Filed: Aug. 13, 2004

(51) Int. Cl. H05K 7/06

(52) U.S. Cl. 361/780; 361/794

(57) ABSTRACT

A multilayer structure comprising a plurality of signal layers and at least one conductive layer other than the signal layers. The multilayer structure also comprises a conductor having a first portion and a second portion contiguous to the first portion, the first portion interconnecting a first one of the signal layers and a second one of the signal layers. The second portion of the conductor is at least partly surrounded by a given one of the at least one conductive layer. The multilayer structure further comprises a conductive structure at least partly surrounding the second portion of the conductor and positioned between the second portion of the conductor and the given one of the at least one conductive layer. A current restricting device is electrically connected to the conductor and to the conductive structure. In addition, the multilayer structure comprises an impedance element electrically connected between the conductive structure and a certain one of the at least one conductive layer. A method of manufacturing such a multilayer structure is also provided.

### FIELD OF THE INVENTION

The present invention relates to multilayer structures such as printed circuit boards (PCBs) and, more particularly, to a device for at least partially alleviating a degradation in signal integrity of signals propagating between different signal layers of the multilayer structure.

### BACKGROUND OF THE INVENTION

A multilayer structure such as a printed circuit board (PCB) usually includes multiple conductors that provide signal paths for routing electrical signals between different layers of the multilayer structure. These conductors are often implemented as vias, which are holes plated or filled with a conductive material.

FIG. 1 shows a conventional via 11 in a portion of a multilayer structure 13. The via 11 provides a signal path for routing an electrical signal between a first signal layer 15₁ and a second signal layer 15₂ of the multilayer structure 13. In this particular case, the via 11 is a through-hole via, wherein the plated or filled hole extends through all the layers of the multilayer structure 13.

One drawback of a through-hole via, such as via 11, is a degradation in signal integrity exhibited by electrical signals routed along the signal path provided by the through-hole via. In particular, as shown in FIG. 1, a portion 17 of the via 11 is seen as extending beyond the region lying between the first signal layer 15₁ and the second signal layer 15₂ that the via 11 is intended to interconnect. This portion 17 of the via 11 interacts with surrounding nearby ground and/or power layers 19₁-19₃ to form what is effectively an open transmission line stub.

The presence of the open stub is deleterious to signals travelling between the first signal layer 15₁ and the second signal layer 15₂. Specifically, an electrical signal arriving at the via 11 from the first signal layer 15₁ enters the via 11 and eventually reaches the point at which the second signal layer 15₂ contacts the via 11. At that point, the electrical signal is split into a first component that enters the second signal layer 15₂ and propagates therein, and a second component that enters the portion 17 of the via 11 and propagates therein. This results in a degradation in signal integrity at the second signal layer 15₂ since only the first component of the electrical signal enters in and propagates through the second signal layer 15₂ at that instant. Furthermore, the second component of the signal propagates in the portion 17 of the via 11 and is reflected by the open termination defined by the lower end of the portion 17. The reflected signal propagates back up along the portion 17 and towards both the second signal layer 15₂ and the first signal layer 15₁. As a result, electrical signals propagating in both of the first and second signal layers 15₁ and 15₂ exhibit a degradation in signal integrity (e.g. change in signal amplitude, increase in phase jitter, etc.).

In an effort to at least partially avoid the degradation in signal integrity associated with open stub portions of through-hole vias, techniques such as the use of blind vias and buried vias have been employed in some multilayer structures. A blind via is a via in which the plated or filled hole extends from only one surface of the multilayer structure to a layer at a certain depth within the multilayer structure. A buried via is a via in which the plated or filled hole does not extend to either surface of the multilayer structure. Blind vias and buried vias can be configured such as to avoid open stub portions that would otherwise be detrimental to signal integrity.

However, providing blind vias and/or buried vias in a multilayer structure entails a substantially more expensive manufacturing process than that used for providing through-hole vias in a multilayer structure. Consequently, for cost considerations, through-hole vias are most often used in multilayer structures despite their associated degradations in signal integrity.

Furthermore, in some cases, avoiding an open stub portion causing degradations in signal integrity is practically impossible. For instance, a circuit card is typically provided with a number of conductive pins which form a connector for electrically coupling the circuit card to a backplane. The backplane is provided with a complementary connector in the form of conductive sleeves extending through the backplane and which receive the pins of the circuit card. The conductive sleeves are usually formed as plated through-holes which cause the same scenario to arise within the backplane multilayer structure as was described above in connection with the conventional through-hole via of FIG. 1.

Accordingly, there is a need in the industry for improvements in multilayer structures geared towards compensating for the deleterious “open stub” effect of through-hole vias.

### SUMMARY OF THE INVENTION

In accordance with a broad aspect, the invention provides a multilayer structure comprising a plurality of signal layers and at least one conductive layer other than the signal layers. The multilayer structure also comprises a conductor having a first portion and a second portion contiguous to the first portion, the first portion interconnecting a first one of the signal layers and a second one of the signal layers. The second portion of the conductor is at least partly surrounded by a given one of the at least one conductive layer. The multilayer structure further comprises a conductive structure at least partly surrounding the second portion of the conductor and positioned between the second portion of the conductor and the given one of the at least one conductive layer. A current restricting device is electrically connected to the conductor and to the conductive structure. In addition, the multilayer structure comprises an impedance element electrically connected between the conductive structure and a certain one of the at least one conductive layer.

In accordance with another broad aspect, the invention provides a method of manufacturing a multilayer structure. The method comprises the steps of:
a) providing a plurality of signal layers;
b) providing at least one conductive layer other than the signal layers;
c) interconnecting a first one of the signal layers and a second one of the signal layers with a first portion of a conductor, the conductor having a second portion contiguous to the first portion and at least partly surrounded by a given one of the at least one conductive layer;
d) at least partly surrounding the second portion of the conductor with a conductive structure positioned between the second portion of the conductor and the given one of the at least one conductive layer;
e) electrically connecting a current restricting device to the conductor and to the conductive structure; and
f) electrically connecting an impedance element between the conductive structure and a certain one of the at least one conductive layer.

In accordance with a further broad aspect, the invention provides a multilayer structure comprising a plurality of signal layers and at least one conductive layer other than the signal layers. The multilayer structure also comprises a conductor having a first portion and a second portion contiguous to the first portion, the first portion interconnecting a first one of the signal layers and a second one of the signal layers. The second portion is at least partly surrounded by a given one of the at least one conductive layer. The multilayer structure further comprises a conductive structure at least partly surrounding the second portion of the conductor and positioned between the second portion of the conductor and the given one of the at least one conductive layer. The multilayer structure also comprises means for restricting a current flow between the conductor and the conductive structure. The means for restricting a current flow between the conductor and the conductive structure includes a first terminal and a second terminal, the first terminal being electrically connected to the conductor and the second terminal being electrically connected to the conductive structure. The means for restricting a current flow between the conductor and the conductive structure substantially prevents flow of an electric current through the first terminal. The multilayer structure also comprises an impedance element electrically connected between the conductive structure and a certain one of the at least one conductive layer.

These and other aspects and features of the present invention will now become apparent to those of ordinary skill in the art upon review of the following description of specific embodiments of the invention in conjunction with the accompanying drawings.

### BRIEF DESCRIPTION OF THE DRAWINGS

A detailed description of specific embodiments of the present invention is provided herein below, by way of example only, with reference to the accompanying drawings, in which:

FIG. 1 is a cross-sectional elevation view of a portion of a multilayer structure including a conventional via;

FIG. 2A is a diagrammatic isometric view of a portion of a multilayer structure including a device for at least partially alleviating a degradation in signal integrity of signals propagating between different signal layers of the multilayer structure, in accordance with a specific example of implementation of the present invention;

FIG. 2B is a diagrammatic isometric view of the multilayer structure shown in FIG. 2A, in which portions of the multilayer structure have been omitted to more clearly show the device for at least partially alleviating a degradation in signal integrity of signals propagating between the different signal layers of the multilayer structure;

FIG. 2C is an elevation view of the multilayer structure shown in FIG. 2B;

FIG. 2D is a cross-sectional view of the multilayer structure shown in FIG. 2C;

FIG. 2E is a model circuit representation of the multilayer structure shown in FIGS. 2A to 2D;

FIG. 3A is a plan view of a certain portion of a conductor of the multilayer structure, wherein the certain portion is completely surrounded by a conductive layer of the multilayer structure, and wherein a conductive structure of the device for at least partially alleviating a degradation in signal integrity of signals propagating between the different signal layers of the multilayer structure completely surrounds the certain portion of the conductor;

FIG. 3B is an elevational view of the device shown in FIG. 3A;

FIG. 3C is a plan view of a certain portion of a conductor of the multilayer structure, wherein the certain portion is only partly surrounded by a conductive layer of the multilayer structure, and wherein a conductive structure of the device for at least partially alleviating a degradation in signal integrity of signals propagating between the different signal layers of the multilayer structure only partly surrounds the certain portion of the conductor;

FIG. 3D is an elevational view of the device shown in FIG. 3C; and

FIG. 4 is diagrammatic view of a non-limiting example of implementation of a current restricting device of the device for at least partially alleviating a degradation in signal integrity of signals propagating between the different signal layers of the multilayer structure.

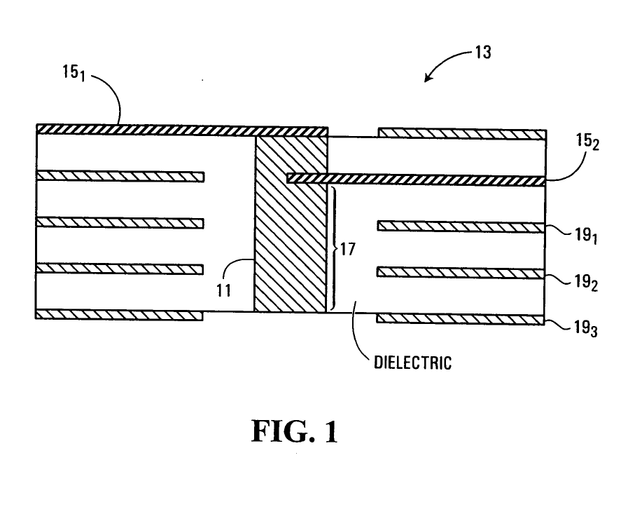

In the drawings, the embodiments of the invention are illustrated by way of examples. It is to be expressly understood that the description and drawings are only for the purpose of illustration and are an aid for understanding. They are not intended to be a definition of the limits of the invention.

### DETAILED DESCRIPTION

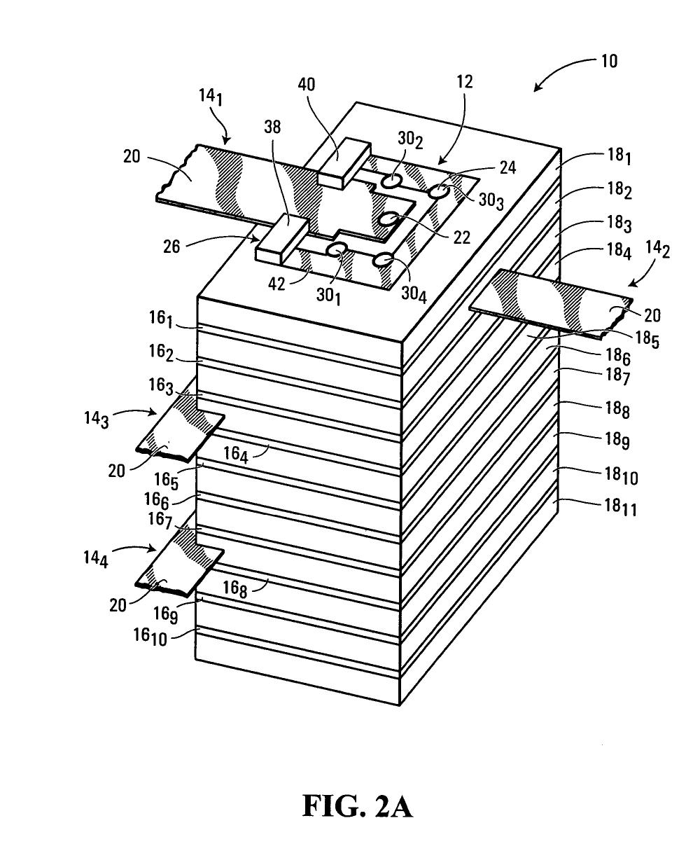

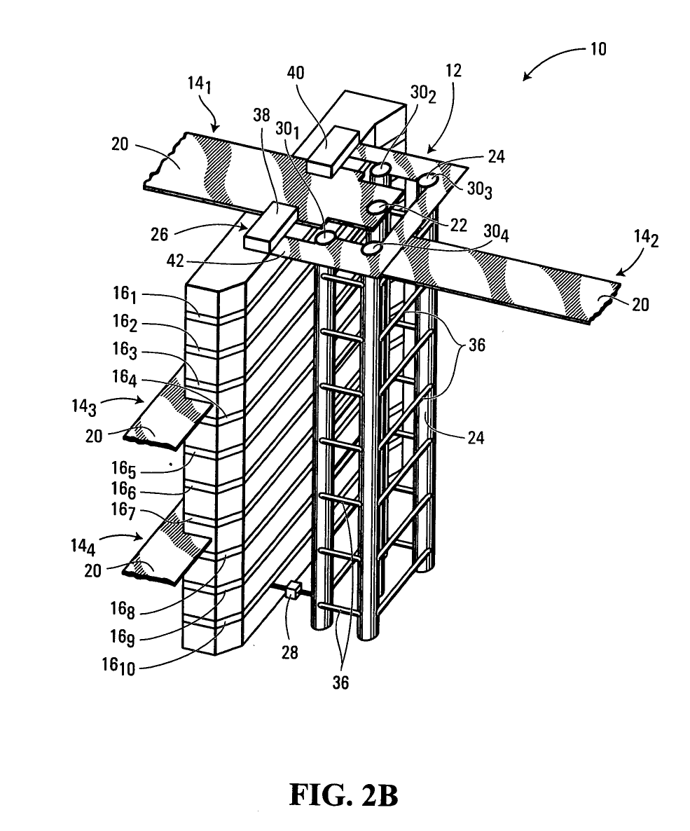

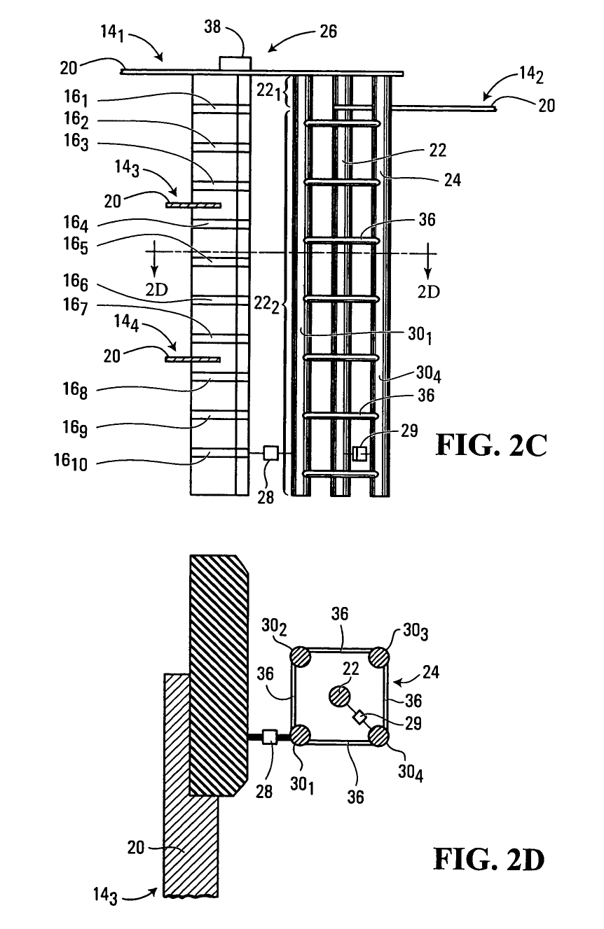

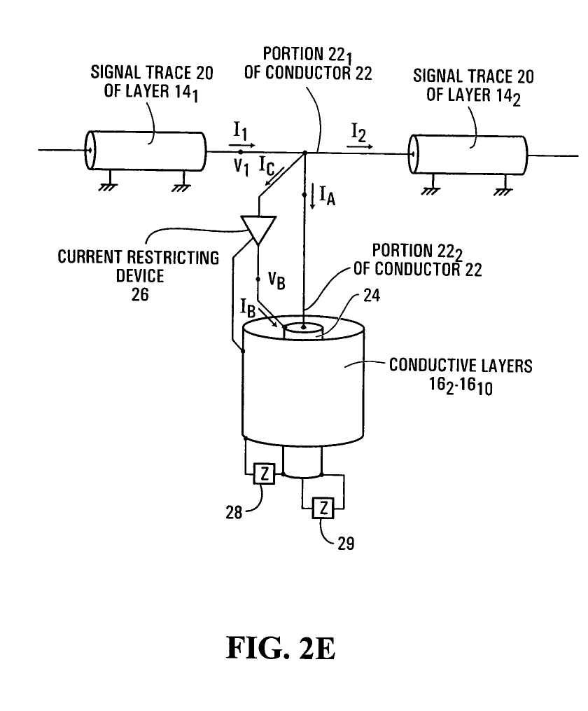

FIG. 2A shows a portion of a multilayer structure 10 that includes a compensatory device 12 in accordance with a specific non-limiting example of implementation of the invention. In the example shown, the multilayer structure 10 is a printed circuit board (PCB). However, it is to be understood that the multilayer structure 10 can be any type of multilayer structure that includes electronic components such as semiconductors, resistors, capacitors, integrated circuits and the like, and in which electrical signals propagate on different layers of the structure.

The multilayer structure 10 includes a plurality of signal layers 14₁-14₄ and a plurality of conductive layers 16₁-16₁₀ other than the signal layers 14₁-14₄. The different layers of the multilayer structure 10 are supported by a support structure which, in the particular example of implementation shown, includes a plurality of dielectric cores 18₁-18₁₁ made of a suitable material such as FR4. In other examples of implementation, the support structure can include various other types of mechanical support elements for supporting the different layers of the multilayer structure 10. Also, the area between any two layers can include any dielectric medium, including a vacuum.

Each one of the signal layers 14₁-14₄ is a layer used for carrying electrical signals and includes at least one signal trace 20 through which electrical signals can travel. The signal trace 20 of each one of the signal layers 14₁-14₄ can be provided in any suitable configuration including but not limited to stripline, microstrip, and coplanar waveguide configurations. Each signal trace 20 is made of electrically conductive material, such as copper, and is formed using known conventional subtractive (e.g. etching) or additive (e.g. deposition) techniques.

Each one of the conductive layers 16₁-16₁₀ is typically either a “ground” layer or a “power” layer. A ground layer provides and distributes an electrical ground. A power layer conducts and distributes a power supply voltage. The conductive layers 16₁-16₁₀ include conductive material such as copper and are thus used to provide signal isolation (i.e. crosstalk reduction) between the signal layers 14₁-14₄ as well as to provide power and grounding to the various components of the multilayer structure 10.

In the specific example of implementation shown, the multilayer structure 10 includes four signals layers 14₁-14₄ and ten conductive layers 16₁-16₁₀ other than the signal layers 14₁-14₄. However, it is to be understood that the multilayer structure 10 can include any number of signal layers as well as any number of conductive layers other than the signal layers. Also, although the specific example of implementation shown presents a particular relative arrangement of the signal layers 14₁-14₄ and the conductive layers 16₁-16₁₀, the signal layers and the conductive layers of the multilayer structure 10 can be positioned relative to each other in various different configurations.

Referring to FIGS. 2A to 2D, the multilayer structure 10 includes a conductor 22 for providing a signal path between different ones of the signal layers 14₁-14₄. The conductor 22 has a first portion 22₁ and a second portion 22₂ contiguous to the first portion 22₁. The first portion 22₁ of the conductor 22 interconnects the signal layer 14₁ and the signal layer 14₂. More particularly, the first portion 22₁ of the conductor 22 is electrically connected to the signal trace 20 of the signal layer 14₁ and to the signal trace 20 of the signal layer 142. The first portion 22₁ of the conductor 22 thus provides a signal path for routing an electrical signal between the signal layers 14₁ and 14₂. It is to be understood that, in other examples of implementation, the first portion 22₁ of the conductor 22 can provide a signal path for routing an electrical signal between any two or more of the signal layers 14₁-14₄ of the multilayer structure 10 without departing from the scope of the invention.

In the particular embodiment shown, the second portion 22₂ of the conductor 22 defines an open stub extending between the signal layer 14₂ and the lower end of the conductor 22. Due to the configuration of the multilayer structure 10, the conductive layers 16₂-16₁₀ surround the second portion 22₂ of the conductor 22. In this particular case, the conductive layers 16₂-16₁₀ completely surround the second portion 22₂ of the conductor 22.

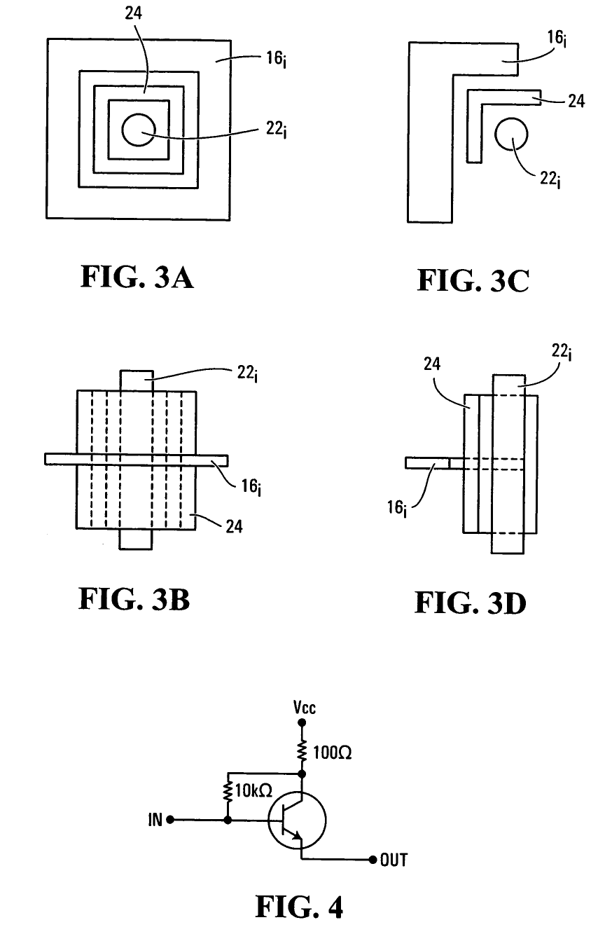

However, referring to FIGS. 3A to 3D, it is to be understood that, generally, the present invention is applicable to any situation wherein a conductor interconnects different signal layers of a multilayer structure and at least one conductive layer 16ᵢ of the multilayer structure at least partly surrounds a portion 22ᵢ of the conductor, wherein the portion 22ᵢ is a portion which is unnecessary for interconnecting the different signal layers. That is, at least one conductive layer 16ᵢ either completely surrounds the portion 22ᵢ of the conductor, as illustrated in FIGS. 3A and 3B, or faces only part of the periphery of the portion 22ᵢ of the conductor, as illustrated in FIGS. 3C and 3D.

In the non-limiting example of implementation of FIGS. 2A to 2D, the conductor 22 is a via, which is a hole plated or filled with a conductive material such as copper or gold. In this case, the via is a through-hole via wherein the plated or filled hole extends through all the layers of the multilayer structure 10. The via can also be a blind via wherein the plated or filled hole extends from an interior layer to only one surface of the multilayer structure 10, or a buried via wherein the plated or filled hole does not extend to either surface of the multilayer structure 10. Advantageously, the manufacturing cost associated to implementing the conductor 22 as a through-hole via is substantially less than that associated to implementing the conductor 22 as a blind via or buried via.

For the remainder of the present description, the conductor 22 will be referred to as a via. However, it is to be understood that, generally, the conductor 22 can be any type of conductive element used for providing a signal path between different signal layers of the multilayer structure 10. For example, the conductor 22 can be a conductive pin inserted and maintained in a hole formed in the multilayer structure 10. For instance, the conductive pin can be a male part of a backplane connector of the multilayer structure 10 for electrically coupling the multilayer structure 10 to a backplane (not shown). Conversely, the multilayer structure 10 itself can be a backplane in which case the conductor 22 can be a female part, such as a conductive sleeve, configured to receive a complementary male part of a backplane connector of another multilayer structure.

With continued reference to FIGS. 2A to 2D, the compensatory device 12 comprises a conductive structure 24, a current restricting device 26, a first impedance element 28, and an optional second impedance element 29. FIG. 2E shows a model circuit representation of the portion of the multilayer structure 10 including the compensatory device 12.

As described in further detail below, the various components of the compensatory device 12 interact such as to at least partially alleviate a degradation in signal integrity of an electrical signal propagating between the signal layers 14₁ and 14₂ along the via 22 due to the presence of the second portion 22₂ of the via 22, which is surrounded by the conductive layers 16₂-16₁₀. In particular, the device 12 is configured such as to substantially prevent a current wave from entering into and propagating in the open stub defined by the second portion 22₂ of the via 22. In return, this substantially prevents the occurrence of a current wave reflecting at the open termination defined by the lower end of the via 22 and propagating back up the via 22 towards the signal layers 14₁ and 14₂. In the particular example of implementation described below, the compensatory device 12 prevents the propagation of such undesired current waves in the second portion 22₂ of the via 22 by substantially nullifying the electric field between the via 22 and the conductive structure 24.

With continued reference to FIGS. 2A to 2D, the conductive structure 24 surrounds the second portion 22₂ of the via 22 and is positioned between the second portion 22₂ of the via 22 and the conductive layers 16₂-16₁₀. Thus, the conductive structure 24 can be envisaged as shielding the second portion 22₂ of the via 22 from the conductive layers 16₂-16₁₀.

In the particular embodiment shown, the conductive structure 24 completely surrounds both the first and second portions 22₁ and 22₂ of the via 22. However, referring to the general case described above in connection with FIGS. 3A to 3D, it is to be understood that the conductive structure 24 may only partly surround the portion 22ᵢ of the via, the portion 22ᵢ being a portion which is unnecessary for interconnecting the different signal layers. That is, the conductive structure 24 may either completely surround the portion 22ᵢ of the via, as illustrated in FIGS. 3A and 3B, or face only part of the periphery of the portion 22ᵢ of the via, as illustrated in FIGS. 3C and 3D.

In the specific example of implementation shown in FIGS. 2A to 2D, the conductive structure 24 is itself made of a number of vias 30₁-30₄. However, these vias 30₁-30₄ are not used for interconnecting signal layers 14₁-14₄ of the multilayer structure 10, i.e. they are not used for providing a signal path from one of the signal layers 14₁-14₄ to another one of the signal layers 14₁-14₄ of the multilayer structure 10. Advantageously, each one of the vias 30₁-30₄ is a through-hole via. Alternatively, each one of the vias 30₁-30₄ can be a blind via or a buried via.

Also, in the particular embodiment of the compensatory device 12 shown in FIGS. 2A to 2D, the vias 30₁-30₄ are interconnected by a plurality of conductive elements 36. The conductive elements 36 can be formed, for instance, during an etching or deposition operation performed on some of the signal layers 14₁-14₄ of the multilayer structure 10. Advantageously, the vias 30₁-30₄ and the conductive elements 36 define a chamber configuration such that the second portion 22₂ of the via 22 is located within the chamber configuration.

While the conductive structure 24 of the non-limiting example of implementation depicted in FIGS. 2A to 2D includes four vias 30₁-30₄ shown to be arranged in a substantially rectangular configuration, it is to be understood that the conductive structure 24 can include any number of vias disposed in any desired configuration. It is also to be understood that, instead of vias, the conductive structure 24 can include a number of conductive pins inserted and maintained in holes formed in the multilayer structure 10. In fact, it is to be understood that the conductive structure 24 can be implemented using any type of structural elements including conductive material, which can be a different material than that used for the via 22.

With continued reference to FIGS. 2A to 2E, the current restricting device 26 is electrically connected to the via 22 and the conductive structure 24. The current restricting device 26 has a first terminal and a second terminal, the first terminal being electrically connected to the via 22 and the second terminal being electrically connected to the conductive structure 24. The current restricting device 26 also has a third terminal that is electrically connected to a particular one of the conductive layers 16₁-16₁₀. The current restricting device 26 serves to restrict flow of an electric current through its first terminal.

In a particular case, the current restricting device 26 prevents as much current as possible from flowing through the first terminal. Nonetheless, due to physical imperfections associated with manufacturing of real-life devices, the current restricting device 26 may still allow some current flow through the first terminal. For example, for a given frequency range of electrical signals propagating in the multilayer structure 10, the current restricting device 26 may be deemed to perform in a satisfactory fashion if it prevents flow through the first terminal of an electric current greater than about 1%, 5% or 10% of an electric current arriving at the first terminal. It will be appreciated by those skilled in the art that other parameters such as, for example, complex impedances, reflection coefficients or S parameters, can be used to characterize the current restricting device 26, and that these other parameters can be translated into a ratio between an electric current flowing into the first terminal and an electric current arriving at the first terminal.

Advantageously, the current restricting device 26 also maintains an electric potential at the second terminal that is substantially identical to an electric potential applied at the first terminal. Again, due to physical imperfections associated with any real-life device, the current restricting device 26 may be only capable of maintaining an electric potential at the second terminal within a certain value from an electric potential applied at the first terminal. For example, for the given frequency range of electrical signals propagating in the multilayer structure 10, the current restricting device 26 may be deemed to perform in a satisfactory fashion if an electric potential at the second terminal is related to an electric potential applied at the first terminal by a ratio lying between about 0.7 and about 1.4.

Therefore, in a particular case, the current restricting device 26 maintains the via 22 and the conductive structure 24 at a substantially identical electric potential and substantially prevents an electric current from flowing through the first terminal electrically connected to the via 22.

The current restricting device 26 having the desired characteristics may include an active component. In the specific example of implementation shown in FIGS. 2A to 2D, the current restricting device 26 includes a first buffer amplifier 38 electrically connected to the via 22 and the conductive structure 24. In this particular case, the first buffer amplifier 38 is a unity gain amplifier. Advantageously, the current restricting device 26 also includes a second buffer amplifier 40 electrically connected to the via 22 and the conductive structure 24, the first and second buffer amplifiers 38 and 40 being in parallel. The second buffer amplifier 40 is also a unity gain amplifier in this specific embodiment. Also, in this particular embodiment, the first and second buffer amplifiers 38 and 40 are each electrically connected to the via 22 and the vias 30₁-30₄ of the conductive structure 24 by way of the signal trace 20 of the signal layer 14₁ and a conductive element 42 formed on the signal layer 14₁.

In a specific embodiment, each one of the buffer amplifiers 38 and 40 is characterized by a gain and an input impedance such that, for the given frequency range of electrical signals routed through the multilayer structure 10, its output voltage is substantially equal to its input voltage and its input current is negligible. One of various possible implementations for each one of the buffer amplifiers 38 and 40 is shown in FIG. 4. A suitable bipolar junction transistor (BJT) for the amplifier is a BFP 620 manufactured by Infineon Technologies.

The current restricting device 26 is characterized by a time delay such that, as a signal is routed between the first and second signal layers 14₁ and 14₂, a voltage wave propagating in the conductive structure 24 is substantially in phase with a voltage wave propagating in the via 22. For example, in the specific example of implementation shown, the delay introduced by each one of the buffer amplifiers 38 and 40 and the conductive element 42 is matched to the delay introduced by the portion of signal trace 20 of the signal layer 14₁ between the buffer amplifiers 38 and 40 and the via 22. The matching can be achieved, for instance, through proper configuration of the signal trace 20 and the conductive element 42.

Thus, in the particular embodiment shown, as an electrical signal propagates between the first and second signal layers 14₁ and 14₂, the current restricting device 26 maintains the via 22 and the conductive structure 24 at a substantially identical electric potential and substantially prevents an electric current from flowing into the first terminal electrically connected to the via 22. While a specific implementation for the current restricting device 26 is depicted in FIGS. 2A to 2D, it will be appreciated by those skilled in the art that various other implementations for the current restricting device 26 are possible and fall within the scope of the present invention.

With continued reference to FIGS. 2A to 2E, the first impedance element 28 is electrically connected between the conductive structure 24 and the conductive layer 16₁₀. It is to be understood that the first impedance element 28 can also be connected to any one of the other conductive layers 16₁-16₉ instead of the conductive layer 16₁₀. In either case, the first impedance element 28 provides a termination to an electrical signal propagating in the conductive structure 24. More particularly, the first impedance element 28 is characterized by an impedance such that an electrical signal having a particular amplitude and propagating in the conductive structure 24 is either completely absorbed by the first impedance element 28 or reflected thereat into an electrical signal having an amplitude less than the particular amplitude.

Specifically, it may be convenient to visualize the conductive structure 24 and the conductive layers 16₂-16₁₀ as defining a transmission line characterized by a characteristic impedance. Advantageously, the impedance of the first impedance element 28 is selected as being substantially identical to the characteristic impedance of the transmission line defined by the conductive structure 24 and the conductive layers 16₂-16₁₀. In that case, the transmission line is said to be matched such that an electrical signal propagating in the conductive structure 24 is completely absorbed by the first impedance element 28.

The characteristic impedance of the transmission line defined by the conductive structure 24 and the conductive layers 16₂-16₁₀ depends on various factors. These factors include the respective configuration and material of the conductive structure 24 and of the conductive layers 16₂₋₁₆₁₀, as well as properties, such as the permittivity and the permeability, of the medium between the conductive structure 24 and the conductive layers 16₂-16₁₀. Advantageously, a model of the multilayer structure 10 including the compensatory device 12 can be built and numerically analyzed using an electromagnetic field simulation tool, such as MEFiSTo-3D Pro™ sold by FAUSTUS Scientific Corporation, Victoria, Canada. A description of that particular electromagnetic field simulation tool can be found at the website http://www.faustcorp.com, the contents of which are hereby incorporated by reference. By varying the impedance of the model's first impedance element 28 and observing the electromagnetic field patterns in the model's conductive structure 24, it is possible to determine the specific impedance of the model's first impedance element 28 which matches the characteristic impedance of the transmission line defined by the model's conductive structure 24 and model's conductive layers 16₂-16₁₀. It is to be understood that other approaches, both analytical and empirical, can also be used without departing from the scope of the invention.

The first impedance element 28 can be implemented using one or more elements such as resistors, capacitors and inductors, or any other suitable elements.

With continued reference to FIGS. 2A to 2E, the second impedance element 29 is electrically connected between the second portion 22₂ of the via 22 and the conductive structure 24. In that way, the second impedance element 29 provides a termination to any electrical signal that, in reality, propagates in the second portion 22₂ of the via 22. While with ideal components the second impedance element 29 need not be used, in reality, the non-ideal characteristics of real-life components of the compensatory device 12 will be such that a difference in electric potential (considered negligible) may exist between the via 22 and the conductive structure 24. Since the second portion 22₂ of the via 22 and the conductive structure 24 define a transmission line characterized by a characteristic impedance, such a difference in electric potential can cause an electric signal to propagate in the second portion 22₂ of the via 22.

Thus, if used, in the interest of perfectionism, the second impedance element 29 is designed to have an impedance such that an electrical signal having a particular amplitude and propagating in the second portion 22₂ of the via 22 is either completely absorbed by the second impedance element 29 or reflected thereat into an electrical signal having an amplitude less than the particular amplitude. Advantageously, the impedance of the second impedance element 29 is substantially equal to the characteristic impedance of the transmission line defined by the second portion 22₂ of the via 22 and the conductive structure 24. In that case, the transmission line is said to be matched such that an electrical signal propagating in the second portion 22₂ of the via 22 is completely absorbed by the second impedance element 29. As described above in connection with the first impedance element 28, the model of the multilayer structure 10 including the compensatory device 12 can be analyzed using an electromagnetic field simulation tool in order to determine the specific impedance of the model's second impedance element 29 which matches the characteristic impedance of the transmission line defined by the second portion 22₂ of the via 22 and the conductive structure 24.

The second impedance element 29 can be implemented using one or more elements such as resistors, capacitors and inductors, or any other suitable elements.

It is to be understood that the second impedance element 29 is optional and can be omitted from the compensatory device 12. The second impedance element 29 can be omitted since any electrical signal that would propagate in the second portion 22₂ of the via 22 is negligible.

In view of the foregoing, and as described in further detail below, it will be appreciated that the various components of the compensatory device 12 interact such as to at least partially alleviate a degradation in signal integrity of an electrical signal propagating between the signal layers 14₁ and 14₂ along the via 22, such degradation being due to the presence of the second portion 22₂ of the via 22, which is surrounded by the conductive layers 16₂-16₁₀.

Specifically, referring to FIGS. 2A to 2E, an electrical signal arriving at the via 22 from the signal trace 20 of the signal layer 14₁ is composed of a voltage wave having a voltage V₁ and a current wave having a current I₁. As the electrical signal reaches the point at which the signal trace 20 of the signal layer 14₂ contacts the via 22, the electrical signal is split into a first component that enters into and propagates in the signal trace 20 of the signal layer 14₂, and a second component that enters into and propagates in the second portion 22₂ of the via 22. The second component is composed of a voltage wave having the same voltage V₁ and a current wave having a current I_{A}.

After the effect of the current restricting device 26, a voltage wave propagates in the conductive structure 24 surrounding the second portion 22₂ of the via 22. This voltage wave has a voltage V_{B} substantially equal in amplitude to the voltage wave propagating in the second portion 22₂ of the via 22. Furthermore, due to the current restricting device 26 and the particular configuration of the signal trace 20 of the signal layer 14₁ and the conductive element 42, the voltage wave propagating in the conductive structure 24 surrounding the second portion 22₂ of the conductor 22 is substantially in phase with the voltage wave propagating in the second portion 22₂ of the via 22. As a result, the voltage difference and thus the electric field between the second portion 22₂ of the via 22 and the conductive structure 24 are substantially null. This causes the current wave propagating in the second portion 22₂ of the via 22 to have a negligible current I_{A} (i.e. I_{A}<<I₁). In addition, the current restricting device 26 allows only a negligible current I_{C} (i.e. I_{C}<<I₁) to be admitted through its first terminal.

By Kirchhoff's current law, the current wave propagating on the signal trace 20 of the signal layer 14₂ has a current I₂=I₁−I_{A}−I_{C}, and from the above it follows that I₂≈I₁. In other words, the current wave arriving from the signal trace 20 of the signal layer 14₁ is substantially entirely carried to the signal trace 20 of the signal layer 14₂.

Meanwhile, the electrical signal propagating in the conductive structure 24 is terminated by the first impedance element 28. Similarly, the (negligible) electrical signal propagating in the second portion 22₂ of the via 22 is terminated by the second impedance element 29.

Although the above discussion related to an electrical signal arriving at the via 22 from the signal trace 20 of the signal layer 14₁, it is to be understood that the discussion also applies to an electrical signal arriving at the via 22 from the signal trace 20 of the signal layer 14₂.

In either case, by substantially nullifying the electric field between the second portion 22₂ of the via 22 and the conductive structure 24, the compensatory device 12 described above substantially prevents the entrance and propagation of undesired current waves in the second portion 22₂ of the via 22. In return, the presence of the first impedance element 28 and optionally the second impedance element 29 substantially prevents the occurrence of a current wave reflecting at the open termination defined by the lower end of the via 22 and propagating back up the via 22 towards the signal layers 14₁ and 14₂.

Finally, it will be appreciated that the compensatory device 12 does not have to substantially nullify the electric field between the second portion 22₂ of the via 22 and the conductive structure 24 in order to be beneficial to the signal integrity of electrical signals propagating through the via 22. Specifically, as long as the compensatory device 12 is such that the difference in electric potential between the second portion 22₂ of the via 22 and the conductive structure 24 is less than a difference in electric potential between the second portion 22₂ of the via 22 and the conductive layers 16₂-16₁₀, the signal integrity of electrical signals propagating through the via 22 will be better than in the absence of the compensatory device 12.

Although various embodiments have been illustrated, this was for the purpose of describing, but not limiting, the invention. Various modifications will become apparent to those skilled in the art and are within the scope of the present invention, which is defined more particularly by the attached claims.

1. A multilayer structure comprising:
a plurality of signal layers;
at least one conductive layer other than said signal layers;
a conductor having a first portion and a second portion contiguous to said first portion, said first portion interconnecting a first one of said signal layers and a second one of said signal layers, said second portion being at least partly surrounded by a given one of said at least one conductive layer;
a conductive structure at least partly surrounding said second portion of said conductor and positioned between said second portion of said conductor and said given one of said at least one conductive layer;
a current restricting device electrically connected to said conductor and to said conductive structure; and
an impedance element electrically connected between said conductive structure and a certain one of said at least one conductive layer.

2. A multilayer structure as defined in claim 1, wherein said conductor is a via.

3. A multilayer structure as defined in claim 1, wherein said conductor is a through-hole via.

4. A multilayer structure as defined in claim 1, wherein said conductor is a conductive pin.

5. A multilayer structure as defined in claim 1, said conductive structure including a via.

6. A multilayer structure as defined in claim 2, said conductive structure including a via.

7. A multilayer structure as defined in claim 5, wherein said via is a through-hole via.

8. A multilayer structure as defined in claim 5, said conductive structure further including a conductive element electrically connected to said via, said conductive element being located on a certain one of said signal layers and at least partly surrounding said second portion of said conductor.

9. A multilayer structure as defined in claim 6, said conductive structure further including a conductive element electrically connected to said via of said conductive structure, said conductive element being located on a certain one of said signal layers and at least partly surrounding said second portion of said conductor.

10. A multilayer structure as defined in claim 1, said conductive structure including a plurality of vias.

11. A multilayer structure as defined in claim 10, wherein at least one of said plurality of vias is a through-hole via.

12. A multilayer structure as defined in claim 10, said conductive structure further including a plurality of conductive elements interconnecting said plurality of vias.

13. A multilayer structure as defined in claim 12, wherein said plurality of vias and said plurality of conductive elements define a chamber configuration, said second portion of said conductor being located within said chamber configuration.

14. A multilayer structure as defined in claim 13, wherein said conductor is a via.

15. A multilayer structure as defined in claim 13, wherein said conductor is a through-hole via.

16. A multilayer structure as defined in claim 1, said current restricting device including a first terminal and a second terminal, said first terminal being electrically connected to said conductor and said second terminal being electrically connected to said conductive structure.

17. A multilayer structure as defined in claim 16, wherein said current restricting device substantially prevents flow of an electric current through said first terminal.

18. A multilayer structure as defined in claim 16, wherein said current restricting device prevents flow through said first terminal of an electric current greater than about 10% of an electric current arriving at said first terminal.

19. A multilayer structure as defined in claim 16, wherein said current restricting device prevents flow through said first terminal of an electric current greater than about 5% of an electric current arriving at said first terminal.

20. A multilayer structure as defined in claim 16, wherein said current restricting device prevents flow through said first terminal of an electric current greater than about 1% of an electric current arriving at said first terminal.

21. A multilayer structure as defined in claim 16, wherein said current restricting device maintains an electric potential at said second terminal substantially identical to an electric potential applied at said first terminal.

22. A multilayer structure as defined in claim 17, wherein said current restricting device maintains an electric potential at said second terminal substantially identical to an electric potential applied at said first terminal.

23. A multilayer structure as defined in claim 16, wherein said current restricting device is such that an electric potential at said second terminal is related to an electric potential applied at said first terminal by a ratio lying between about 0.7 and about 1.4.

24. A multilayer structure as defined in claim 16, said current restricting device further including a third terminal electrically connected to a particular one of said at least one conductive layer.

25. A multilayer structure as defined in claim 1, said current restricting device including an active component.

26. A multilayer structure as defined in claim 1, said current restricting device including a buffer amplifier.

27. A multilayer structure as defined in claim 1, said current restricting device including a unity gain amplifier.

28. A multilayer structure as defined in claim 26, wherein said buffer amplifier is a first buffer amplifier, said current restricting device including a second buffer amplifier, said first and second buffer amplifiers being connected in parallel.

29. A multilayer structure as defined in claim 28, wherein each of said first and second buffer amplifiers is embodied as a unity gain amplifier.

30. A multilayer structure as defined in claim 1, wherein said impedance element provides a termination for an electrical signal propagating in said conductive structure.

31. A multilayer structure as defined in claim 1, wherein said impedance element comprises at least one element selected from the group consisting of a resistor, a capacitor, and an inductor.

32. A multilayer structure as defined in claim 1, wherein said conductive structure and said given one of said at least one conductive layer define a transmission line characterized by a characteristic impedance, said impedance element having an impedance substantially identical to the characteristic impedance of the transmission line.

33. A multilayer structure as defined in claim 1, wherein said impedance element is a first impedance element, said multilayer structure further comprising a second impedance element electrically connected to said conductor and said conductive structure.

34. A multilayer structure as defined in claim 33, wherein said second impedance element provides a termination for an electrical signal propagating in said second portion of said conductor.

35. A multilayer structure as defined in claim 33, wherein said second impedance element comprises at least one element selected from the group consisting of a resistor, a capacitor, and an inductor.

36. A multilayer structure as defined in claim 33, wherein said second portion of said conductor and said conductive structure define a transmission line characterized by a characteristic impedance, said second impedance element having an impedance substantially identical to the characteristic impedance of the transmission line.

37. A multilayer structure as defined in claim 36, wherein the transmission line defined by said second portion of said conductor and said conductive structure is a first transmission line, said conductive structure and said given one of said at least one conductive layer defining a second transmission line characterized by a characteristic impedance, said first impedance element having an impedance substantially identical to the characteristic impedance of the second transmission line.

38. A printed circuit board comprising the multilayer structure defined in claim 1.

39. A backplane comprising the multilayer structure defined in claim 1.

40. A method of manufacturing a multilayer structure, said method comprising:
a) providing a plurality of signal layers;
b) providing at least one conductive layer other than the signal layers;
c) interconnecting a first one of the signal layers and a second one of the signal layers with a first portion of a conductor, the conductor having a second portion contiguous to the first portion, the second portion being at least partly surrounded by a given one of the at least one conductive layer;
d) at least partly surrounding the second portion of the conductor with a conductive structure positioned between the second portion of the conductor and the given one of the at least one conductive layer;
e) electrically connecting a current restricting device to the conductor and to the conductive structure; and
f) electrically connecting an impedance element between the conductive structure and a certain one of the at least one conductive layer.

41. A method as defined in claim 40, wherein, in step c), the conductor is realized by forming a via.

42. A method as defined in claim 41, wherein the via is a through-hole via.

43. A method as defined in claim 40, wherein, in step c), the conductor is realized by inserting a conductive pin in a hole formed in the multilayer structure.

44. A method as defined in claim 40, wherein, in step e), the current restricting device includes a first terminal and a second terminal, the first terminal being electrically connected to the conductor and the second terminal being electrically connected to the conductive structure.

45. A method as defined in claim 44, in operation, the current restricting device substantially preventing flow of an electric current through the first terminal.

46. A method as defined in claim 44, in operation, the current restricting device maintaining an electric potential at the second terminal substantially identical to an electric potential applied at the first terminal.

47. A method as defined in claim 40, further comprising selecting an impedance of the impedance element by building a model of the multilayer structure and analyzing the model using an electromagnetic field simulation tool.

48. A method as defined in claim 47, wherein analyzing comprises varying an impedance of a model representation of the impedance element and observing an electromagnetic field pattern in a model representation of the conductive structure so as to determine a certain impedance of the model representation of the impedance element which substantially matches a characteristic impedance of a transmission line defined by the model representation of the conductive structure and a model representation of the at least one conductive layer.

49. A method as defined in claim 40, wherein, in step f), the impedance element is a first impedance element, said method further comprising:
g) electrically connecting a second impedance element to the conductor and the conductive structure.

50. A method as defined in claim 49, further comprising selecting an impedance of the second impedance element by building a model of the multilayer structure and analyzing the model using an electromagnetic field simulation tool.

51. A method as defined in claim 50, wherein analyzing comprises varying an impedance of a model representation of the second impedance element and observing an electromagnetic field pattern in a model representation of the conductor so as to determine a certain impedance of the model representation of the second impedance element which substantially matches a characteristic impedance of a transmission line defined by the model representation of the conductor and a model representation of the conductive structure.

52. A multilayer structure comprising:
a plurality of signal layers;
at least one conductive layer other than said signal layers;
a conductor having a first portion and a second portion contiguous to said first portion, said first portion interconnecting a first one of said signal layers and a second one of said signal layers, said second portion being at least partly surrounded by a given one of said at least one conductive layer;
a conductive structure at least partly surrounding said second portion of said conductor and positioned between said second portion of said conductor and said given one of said at least one conductive layer;
means for restricting a current flow between said conductor and said conductive structure, said means including a first terminal and a second terminal, said first terminal being electrically connected to said conductor and said second terminal being electrically connected to said conductive structure, said means substantially preventing flow of an electric current through said first terminal; and
an impedance element electrically connected between said conductive structure and a certain one of said at least one conductive layer.
